(19) United States
(12) Patent Application Publication
(10) Pub. No.: US 2025/0392214 A1
(43) Pub. Date: Dec. 25, 2025

(54) CIRCUITRY FOR SUPPLYING A BIAS VOLTAGE

(71) Applicant: Cirrus Logic International Semiconductor Ltd., Edinburgh (GB)

(72) Inventors: Deep SAXENA, Edinburgh (GB); Hamed SADATI, Newbury (GB); Gary J. ROBERTSON, Edinburgh (GB); Vivek SARAF, Edinburgh (GB); David J. SMITH, Edinburgh (GB)

(73) Assignee: Cirrus Logic International Semiconductor Ltd., Edinburgh (GB)

(21) Appl. No.: 19/040,274

(22) Filed: Jan. 29, 2025

Related U.S. Application Data
(60) Provisional application No. 63/662,494, filed on Jun. 21, 2024.

(51) Int. Cl. H02M 3/156; H03K 19/20

(52) U.S. Cl. CPC H02M 3/156; H03K 19/20

(57) ABSTRACT

Circuitry for supplying a bias voltage to a replica sense device of current sensing circuitry for a switch of a switching circuit, the circuitry comprising: multiplexer circuitry configured to receive a first voltage and a second voltage, wherein the first voltage is a floating voltage and the second voltage is a fixed voltage, wherein the multiplexer circuitry is configured to select and output one of the first voltage and the second voltage, such that the first voltage is output by the multiplexer circuitry when the switch is switched on and the second voltage is output by the multiplexer circuitry when the switch is switched off.

### FIELD OF THE INVENTION

The present disclosure relates to circuitry for supplying a bias voltage, in particular a bias voltage for a replica sense device used in current sensing for a switch of a switching circuit.

### BACKGROUND

In many switching circuits, including for example switching power converters, switching amplifiers and the like, the switching circuit includes a high-side switch which, when closed (switched on), connects a node of the circuit to another node or terminal of the circuit that is at a relatively high voltage level. In many cases the high-side switch is an NMOS MOSFET device.

### SUMMARY

According to a first aspect, the invention provides circuitry for supplying a bias voltage to a replica sense device of current sensing circuitry for a switch of a switching circuit, the circuitry comprising: multiplexer circuitry configured to receive a first voltage and a second voltage, wherein the first voltage is a floating voltage and the second voltage is a fixed voltage, wherein the multiplexer circuitry is configured to select and output one of the first voltage and the second voltage, such that the first voltage is output by the multiplexer circuitry when the switch is switched on and the second voltage is output by the multiplexer circuitry when the switch is switched off.

A magnitude of the second voltage may be approximately equal to an expected magnitude of the first voltage when the switch of the switching circuit is switched on.

The switch may comprise a MOSFET (metal oxide semiconductor field effect transistor). The replica sense device may comprise a MOSFET smaller than the MOSFET of the switch.

The second voltage may be of a magnitude sufficient to maintain a common mode voltage for differential amplifier circuitry of the current sensing circuitry.

The second voltage may be of a magnitude sufficient to maintain the replica sense device in a safe operating area thereof.

The multiplexer may be configured to output the selected voltage to a gate of the replica sense device.

The multiplexer circuitry may be configured to select the greater of the first voltage and the second voltage.

The multiplexer circuitry may comprise: first select switch circuitry configured to be controlled by first control circuitry; and second select switch circuitry configured to be controlled by second control circuitry.

The first select switch circuitry may comprise first and second p-channel MOSFETs coupled in series between a first input node and an output node of the multiplexer circuitry. The second select switch circuitry may comprise third and fourth p-channel MOSFETs coupled in series between a second input node and the output node of the multiplexer circuitry.

The first input node may receive the second voltage. The second input node may receive the first voltage.

The first select switch circuitry may be configured to decouple the first input node from the output node of the multiplexer circuitry when the switch is switched on and to couple the first input node to the output node of the multiplexer circuitry when the switch is switched off. The second select switch circuitry may be configured to couple the second input node to the output node of the multiplexer circuitry when the switch is switched on and to decouple the second input node from the output node of the multiplexer circuitry when the switch is switched off.

The first select switch circuitry may comprise a first control node configured to receive an output of the first control circuitry. The second select switch circuitry may comprise a second control node configured to receive an output of the second control circuitry. The first control circuitry and the second control circuitry may each be configured to output the greater of the first voltage and the second voltage.

The first control circuitry and the second control circuitry each comprise highest voltage selector circuitry configured to output the greater of the first voltage and the second voltage.

The highest voltage selector circuitry may implement an OR circuit.

The switching circuitry may comprise, for example, switching power converter circuitry comprising a bootstrap capacitor. The circuitry may further comprise a switch configured to selectively couple a power supply rail to the bootstrap capacitor to supply charge to the bootstrap capacitor.

The circuitry may be configured to close the switch to couple the power supply rail to the bootstrap capacitor in a non-conducting phase in operation of the switching power converter circuitry in a discontinuous conduction mode.

According to a second aspect, the invention provides an integrated circuit comprising the circuitry of the first aspect.

According to a third aspect, the invention provides a host device comprising the circuitry of the first aspect.

The host device may comprise, for example, a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer.

According to a fourth aspect, the invention provides circuitry for supplying a bias voltage to a replica sense device used in current sensing for a switch of a switching circuit, the circuitry comprising multiplexer circuitry configured to receive a first voltage and a second voltage, wherein the first voltage is a floating voltage and the second voltage is a fixed voltage, wherein the multiplexer circuitry is configured to select and output a highest one of the first voltage and the second voltage.

According to a fifth aspect, the invention provides switching power converter circuitry operable in a continuous conduction mode or a discontinuous conduction mode, the switching power converter circuitry comprising: a bootstrap capacitor for supplying a bootstrap voltage to a power switch of the switching power converter circuitry; a power supply rail; and a switch for selectively coupling the power supply rail to the bootstrap capacitor, wherein, in operation of the switching power converter circuitry in the discontinuous conduction mode, the switch is closed to couple the power supply rail to the bootstrap capacitor in a non-conducting phase of operation.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a is a simplified schematic representation of example boost converter circuitry;

FIG. 2 is a simplified schematic representation of example current monitor circuitry using replica devices;

FIG. 3 is a simplified schematic representation of multiplexer circuitry for selecting between two input voltages;

FIG. 4 is a schematic diagram illustrating an example configuration of multiplexer circuitry suitable for use as the multiplexer circuitry of FIG. 3;

FIG. 5 is a schematic representation of circuitry for selecting a highest voltage between first and second input voltages;

FIG. 6 is a schematic representation of circuitry for maintaining charge on a bootstrap capacitor of switching circuitry when the switching circuitry is operating in a discontinuous conduction mode.

### DETAILED DESCRIPTION

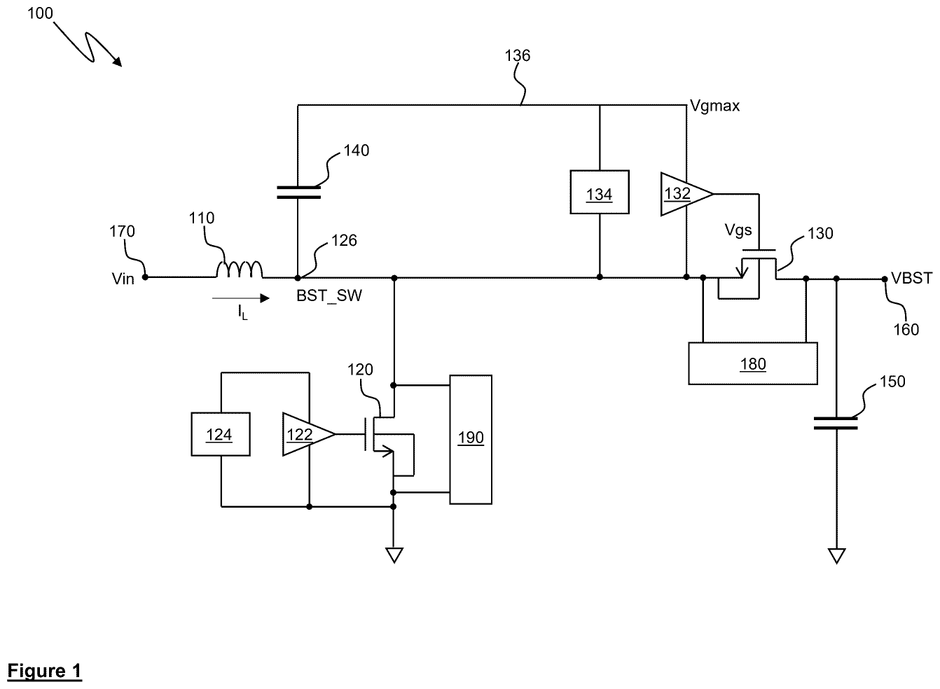

FIG. 1 is a simplified schematic representation of example boost converter circuitry.

The boost converter circuitry (shown generally at 100 in FIG. 1) includes an inductor 110, a low-side switch 120 (which in this example is an N-channel MOSFET), low-side gate driver circuitry 122 for supplying a gate drive voltage to a gate of the low-side switch 120, and low-side supply generator circuitry 124 configured to provide a supply voltage to the low-side gate driver circuitry 122. The boost converter circuitry 100 further includes a high-side switch 130 (which in this example is also an N-channel MOSFET), high-side gate driver circuitry 132 for supplying a gate drive voltage to a gate of the high-side switch 130 is coupled, and high-side supply generator circuitry 134 configured to provide a supply voltage to the high-side gate driver circuitry 132. The low-side switch 120 and the high-side switch 130 may be referred to as power switches.

The boost converter circuitry 100 further includes a bootstrap capacitor 140 coupled in parallel with the high-side supply generator circuitry 134 to supply a bootstrap voltage to the high-side gate driver circuitry 132. A first terminal of the bootstrap capacitor 140 and a first terminal of the high-side supply generator 134 are each coupled to a node 126 between the inductor and the low-side switch 120.

The boost converter circuitry 100 further includes a reservoir capacitor 150 coupled between an output node 160 of the boost converter circuitry 100 and a ground or other reference voltage supply rail (hereinafter referred to as ground, for simplicity).

The inductor 110 is coupled in series between an input node 170 at which an input voltage Vin to the boost converter circuitry 100 is received and a drain terminal of the low-side switch 120. A source terminal of the low-side switch 120 is coupled to ground, and a gate terminal of the low-side switch 120 is coupled to an output of the low-side gate driver circuitry 122.

A source terminal of the high-side switch 130 is coupled to the inductor 110 and a drain terminal of the high-side switch 130 is coupled to the output node 160, at which an output voltage VBST of the boost converter circuitry 100 is supplied. A gate terminal of the high-side switch 130 is coupled to the output of the high-side driver circuitry 132, such that the gate terminal of the high-side switch 130 receives a gate drive voltage Vgs from the high-side driver circuitry 132.

In operation of the boost converter circuitry 100, the low-side switch 120 and the high-side switch 130 are controlled to switch on alternately so as to repeatedly couple one terminal of the inductor 110 to ground and then to the output node 160, such that energy can be transferred from the inductor 110 to the reservoir capacitor 150 to increase the output voltage VBST across the reservoir capacitor 150 to a level that is greater than the input voltage Vin.

In a first, charging, phase of operation of the circuitry 100, control circuitry (not shown in FIG. 1 for simplicity) outputs control signals to the low-side and high-side switches 120, 130 to switch the low-side switch 120 on, and to switch the high-side switch 130 off. Thus, during the charging phase, a current path exists from the input node 170 to ground through the inductor 110, and an increasing current IL flows through the inductor 110. As a result of the increasing inductor current IL, the inductor stores energy by generating a magnetic field.

In a second, discharging, phase, of operation of the circuitry 100, the control circuitry outputs control signals to the low-side and high-side switches 120, 130 to switch the low-side switch 120 off, and to switch the high-side switch 130 on. Thus, during the discharging phase, current can no longer flow through the inductor 110 to ground through the low-side switch 120. The current in the inductor 110 must keep flowing, and therefore flows into the reservoir capacitor 150, causing the voltage VBST across the reservoir capacitor 150 to increase. If VBST is smaller than Vin the current in the inductor 110 will continue to increase, hence charging the reservoir capacitor 150. If VBST is greater than Vin the current in the inductor 110 will start decreasing, but because the current is still positive the voltage VBST across the reservoir capacitor 150 will continue to increase further.

By repeating the charging phase and the discharging phase a number of times, the reservoir capacitor 150 can be charged to a level at which the voltage VBST across the reservoir capacitor 150 is greater than the input voltage Vin and is thus suitable for supplying downstream components or subsystems such as amplifier circuitry or the like that require a voltage greater voltage than Vin.

When the node 126 between the inductor 110 and the low-side switch 120 is low (when the low-side switch 120 is switched on and the high-side switch 130 is switched off, in the charging phase), the bootstrap capacitor 140 is charged by the high-side supply generator circuitry 134. When the low-side switch 120 is switched off and the high-side switch 130 is switched on in the discharging phase, the inductor current IL drives a voltage BST_SW at the node 126 to VBST. The voltage across the bootstrap capacitor 140, and thus a voltage Vgmax at a floating voltage rail 136 (which couples a second terminal of the bootstrap capacitor 140 to a second terminal of the high-side supply generator circuitry 134 and provides a supply voltage to the high-side driver circuitry 132) will follow the voltage BST_SW at the node 126, such that the voltage Vgmax at the floating voltage rail 136 is applied across the gate-source of the high-side switch 130 as the gate drive voltage Vgs. The bootstrap capacitor 140, high-side supply generator circuitry 134 and high-side driver circuitry 132 may be configured such that the voltage Vgmax at the floating voltage rail 136 is, for example, 5 volts higher than the voltage BST_SW at the node 126. In such an example, when the high-side switch 130 is switched on, the voltage Vgmax at the floating voltage rail 136 is equal to BST_SW+5V, whereas when the high-side switch 130 is switched off, the voltage Vgmax at the floating voltage rail 136 is equal to 5V.

Accurate sensing and regulation of the inductor current IL is desirable in boost converter circuitry 100 of the kind shown in FIG. 1, to optimise control of the boost converter circuitry 100. The inductor current IL during the discharge phase of operation of the boost converter circuitry 100 can be determined based on the current through the high-side switch 130. To this end, the boost converter circuitry 100 of FIG. 1 includes current monitor circuitry 180 configured to monitor current through the high-side switch 130 (and may also include current monitor circuitry 190 configured to monitor current through the low-side switch 120).

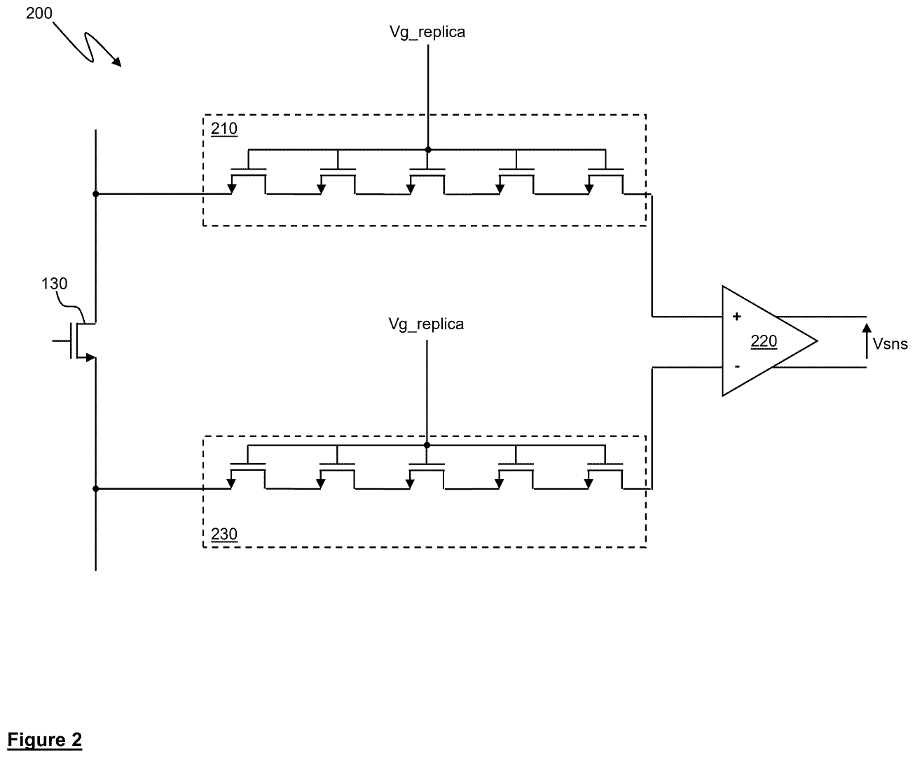

FIG. 2 is a simplified schematic representation of current monitor circuitry for monitoring current through the high-side switch 130 of the boost converter circuitry 100.

The current monitor circuitry, shown generally at 200 in FIG. 2, comprises a first plurality of replica devices, which are smaller replicas of the high-side switch 130 (e.g. N-channel MOSFETs that are smaller than the high-side switch 130, where the high-side switch 130 is an N-channel MOSFET) 210 coupled between a first terminal (e.g. a drain terminal) of the high-side switch 130 and a first (e.g. non-inverting) input of differential amplifier circuitry 220. A second plurality of replica devices (e.g. smaller replicas of the high-side switch 130) 230 is coupled between a second terminal (e.g. a source terminal) of the high-side switch 130 and a second (e.g. non-inverting) input of the differential amplifier circuitry 220.

In operation of the current monitor circuitry 200, a proportion of the current that flows through the high-side switch 130 when it is switched on flows through the first plurality of replica devices 210 and through the second plurality of replica devices 230. A differential voltage Vsns at between differential first and second outputs of the differential amplifier circuitry 220 is indicative of the current through the high-side switch 130.

It is to be appreciated that FIG. 2 and the description above are simplified to facilitate understanding of the present disclosure. A detailed explanation of the structure and operation of such current monitor circuitry is provided in U.S. provisional patent application No. 63/595,833 and U.S. patent application Ser. No. 18/590,241, the contents of which are incorporated by reference herein.

Replica-based current monitor circuitry of the kind described in in U.S. provisional patent application No. 53/595,833 and U.S. patent application Ser. No. 18/590,241 provides a low-power means for monitoring current through the high-side switch 130 (and the low-side switch 120). However, such replica-based current monitor circuitry may suffer from low accuracy, for example due to drift in a gain of the replica devices. One contributor to error (and thus inaccuracy) in replica-based current monitoring circuitry is a difference between a gate drive voltage supplied to the gate of the switch being monitored (e.g. the high-side switch 130) and a gate drive voltage supplied to the gates of the replica devices 210, 230.

To mitigate the risk of error in replica-based current monitoring circuitry, the gate drive voltage supplied to the gates of the replica devices 210, 230 should be as close as possible to the gate drive voltage Vgs that is supplied to the gate of the switch being monitored (e.g. the high-side switch 130 in the example boost converter circuitry 100 of FIG. 1).

The gate drive voltage supplied to the gates of the replica devices 210, 230 may be supplied by a voltage source such as a charge pump. However, the output voltage of such a voltage source may drift due to factors such as temperature and load. In some implementations of boost converter circuitry with replica-based current sensing where the gate drive voltage supplied to the gates of the replica devices is supplied by a voltage source such as a charge pump, a change of around 1 volt in the output voltage of the voltage source can lead to measurement error of 10-12% in the current sensing circuitry.

The present disclosure thus proposes to mitigate the risk of error in replica-based current monitoring circuitry by supplying the gate drive voltage Vgs that is supplied to the gate of the switch being monitored, e.g. the high-side switch 130, to the gates of the replica devices 210, 230.

Thus, as shown in FIG. 2, a voltage Vg_replica equal to the gate drive voltage Vgs supplied to the high-side switch 130 is supplied to the gates of all the replica devices 210, 230. This may be achieved, for example, by coupling the gates of all the replica devices 210, 230 to the floating voltage rail 136 of the boost converter circuitry 100 of FIG. 1.

Supplying the same gate drive voltage to the gates of the replica devices 210, 230 as is supplied to the gate of the switch being monitored (e.g. the high-side switch 130) minimises any difference between the gate drive voltages of the switch being monitored and those of the replica devices 210, 230, thus minimising current measurement error arising from such a difference in gate drive voltages.

The current through the high-side switch 130 need only be monitored during the discharging phase of the boost converter circuitry 100, i.e. when the high-side switch 130 is switched on. Thus, during the discharging phase of the boost converter circuitry 100, the gate drive voltage that is supplied to the high-side switch 130 can also be supplied to each of the plurality of replica devices 210, 230 to minimise or at least reduce error in the current monitoring performed by the current monitor circuitry 200.

When the high-side switch 130 is switched off, e.g. during the charging phase of the boost converter circuitry 100, it is desirable to continue to provide a bias voltage to each of the plurality of replica devices 210, 230 to maintain a common mode voltage for the differential amplifier circuitry 220. Continuing to provide a bias voltage to each of the plurality of replica devices 210, 230 when the high-side switch 130 is switched off may also help to ensure that the replica devices 210, 230 can rapidly switch on when the boost converter circuitry 100 enters a new discharging phase to ensure accurate sensing of the current through the high-side switch.

However, the gate drive voltage supplied to the gate of the high-side switch 130 when the high-side switch 130 is switched off (during the charging phase of the boost converter circuitry 100) may be unsuitable for biasing the replica devices 210, 230, as it may be insufficient to maintain the common mode voltage for the differential amplifier circuitry 220. The gate drive voltage supplied to the gate of the high-side switch 130 when the high-side switch 130 is switched off may also be insufficient to maintain the replica devices 210, 230 in their safe operating areas.

Accordingly, it would be desirable to provide a system capable of supplying the same gate drive voltage to the gate of the high-side switch 130 and to the gates of the replica devices 210, 230 when the high-side switch 130 is switched on (to minimise inaccuracy in measurement of the current though the high-side switch 130 when it is switched on), and supplying a gate drive voltage to the replica devices 210, 230 that maintains the common mode voltage for differential amplifier circuitry of replica-based current monitoring circuitry including replica devices 210, 230 when the high-side switch 130 is not switched on. It may also be beneficial if the gate drive voltage supplied to the replica devices 210, 230 when the high-side switch 130 is switched off were sufficient to maintain the replica devices 210, 230 in their safe operating area when the high-side switch 130 is not switched on.

To this end, the present disclosure proposes multiplexer circuitry that selects between a substantially fixed voltage of a magnitude sufficient to maintain the common mode voltage for differential amplifier circuitry of replica-based current monitoring circuitry of the kind described above with reference to FIG. 2 and the voltage Vgmax at the floating voltage rail 136, such that when the high-side switch 130 is switched on the voltage Vgmax is supplied to the gates of the replica devices 210, 230 and when the high-side switch 130 is switched off, the substantially fixed voltage is supplied to the gates of the replica devices 210, 230. It may be advantageous if the substantially fixed voltage were sufficient to maintain the replica devices 210, 230 in their safe operating area.

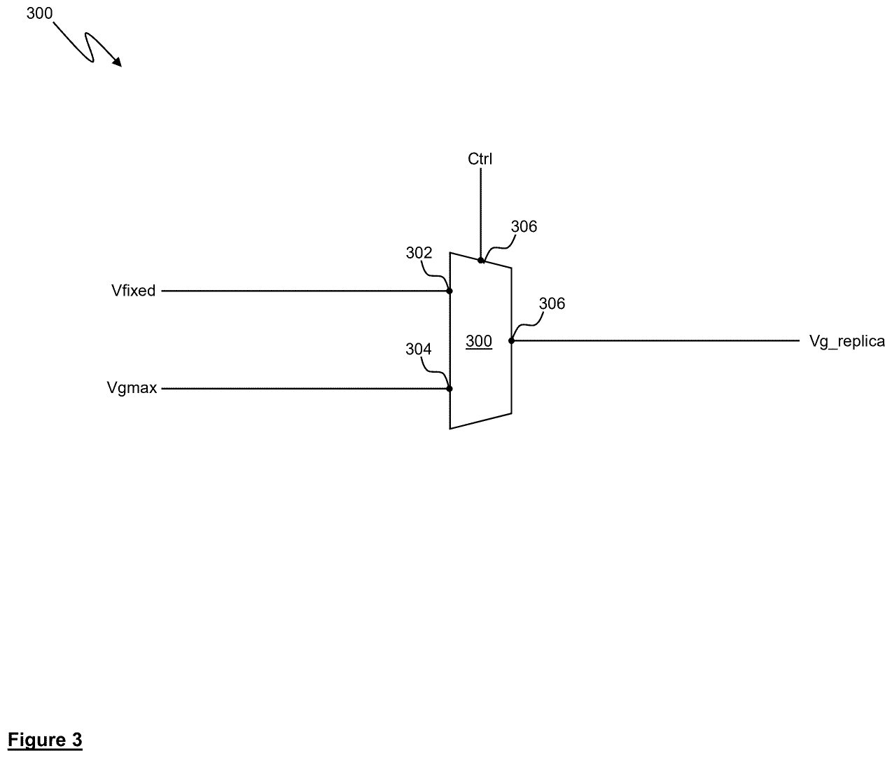

This is illustrated schematically in FIG. 3, which shows multiplexer circuitry 300 having a first input 302 that receives a substantially fixed voltage Vfixed (e.g. from a charge pump or other voltage source) of a magnitude sufficient to maintain a common mode voltage for differential amplifier circuitry of replica-based current sensing circuitry (and, in some examples, also sufficient to maintain the replica devices 210, 230 in their safe operating area), a second input 304 that receives the voltage Vgmax at the floating voltage rail 136 and an output 306 that outputs a voltage Vg_replica to the gates of the replica devices 210, 230. The magnitude of the substantially fixed voltage Vfixed may be equal to (at least approximately, e.g. within 0.1V of) an expected magnitude of the voltage Vgmax at the floating voltage rail 136 which is applied across the gate-source of the high-side switch 130 as the gate drive voltage Vgs when the high-side switch 130 is switched on. The multiplexer circuitry 300 may further include a control input 308 for receiving a control signal Ctrl indicative of the state (on or off) of the high-side switch 130, e.g. from controller circuitry of the boost converter circuitry 100 or from detection circuitry configured to detect the state of the high-side switch 130. The multiplexer circuitry 300 may be configured to select between the substantially fixed voltage and the voltage Vgmax based on the state of the high-side switch 130, as indicated, for example, by the control signal Ctrl.

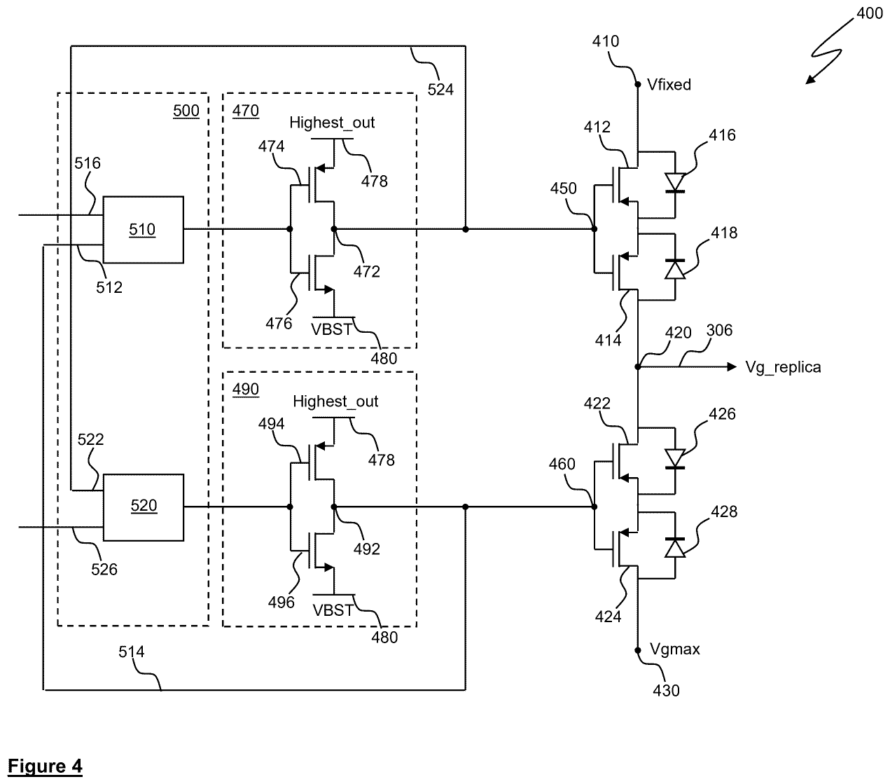

FIG. 4 is a schematic diagram illustrating an example configuration of multiplexer circuitry suitable for use as the multiplexer circuitry 300 of FIG. 3.

The multiplexer circuitry, shown generally at 400 in FIG. 4, comprises first and second P-channel MOSFETs (metal oxide semiconductor field effect transistors) 412, 414 coupled in series between a first input node 410 and an output node 420 of the multiplexer circuitry 400. The first input node 410 receives the substantially fixed voltage Vfixed. A gate terminal of the first MOSFET 412 is coupled to a gate terminal of the second MOSFET 414. A drain terminal of the first MOSFET 412 is coupled to the first input node 410 and a source terminal of the first MOSFET 412 is coupled to a source terminal of the second MOSFET 414. A drain terminal of the second MOSFET 414 is coupled to the output node 420. A first diode 416 (which may be a body diode of the first MOSFET 412) is coupled to the first MOSFET 412, with its anode coupled to the drain terminal of the first MOSFET 412 and its cathode coupled to the source terminal of the first MOSFET 412. A second diode 418 (which may be a body diode of the second MOSFET 414) is coupled to the second MOSFET 414, with its anode coupled to the drain terminal of the second MOSFET 414 and its cathode coupled to the source terminal of the second MOSFET 414.

The combination of the first and second P-channel MOSFETs 412, 414 constitutes first select switch circuitry which, when activated, selects the substantially fixed voltage Vfixed as the output voltage Vg_replica of the multiplexer circuitry 300.

The multiplexer circuitry 400 further comprises third and fourth P-channel MOSFETS 422, 424 coupled in series between a second input node 430 and the output node 420. The second input node 430 receives the voltage Vgmax. A gate terminal of the third MOSFET 422 is coupled to a gate terminal of the fourth MOSFET 424. A drain terminal of the third MOSFET 422 is coupled to the output node 420 and a source terminal of the third MOSFET 422 is coupled to a source terminal of the fourth MOSFET 424. A drain terminal of the fourth MOSFET 424 is coupled to the second input node 430. A third diode 426 (which may be a body diode of the third MOSFET 422) is coupled to the third MOSFET 422, with its anode coupled to the drain terminal of the third MOSFET 422 and its cathode coupled to the source terminal of the third MOSFET 422. A fourth diode 428 (which may be a body diode of the second MOSFET 414) is coupled to the fourth MOSFET 424, with its anode coupled to the drain terminal of the fourth MOSFET 424 and its cathode coupled to the source terminal of the fourth MOSFET 424.

The combination of the third and fourth P-channel MOSFETs 422, 424 constitutes second select switch circuitry which, when activated, selects the voltage Vgmax as the output voltage Vg_replica of the multiplexer circuitry 300.

The first diode 416 prevents back flow of current to the first input node 410 when the third and fourth MOSFETS 422, 424 are switched on to supply the voltage Vgmax to the output node 420. Similarly, the fourth diode 428 prevents back flow of current to the second input node 430 when the first and second MOSFETS 412, 414 are switched on to supply the substantially fixed voltage Vfixed to the output node 420. The second diode 418 prevents a flow of current from the first input node 410 to the output node 420 when the first and second P-channel MOSFETs 412, 424 are switched off. Similarly, the fourth diode 428 prevents a flow of current from the second input node 430 to the output node when the third and fourth P-channel MOSFETs 422, 424 are switched off.

The gate terminals of the first and second MOSFETS 412, 414 are coupled to a first control node 450. The first control node 450 is also coupled to an output node 472 of first control circuitry 470.

The gate terminals of the third and fourth MOSFETs 422, 424 are coupled to a second control node 460. The second control node 460 is also coupled to an output node 492 of second control circuitry 490.

The first control circuitry 470 in this example comprises a first P-channel MOSFET 474 coupled in series with a first N-channel MOSFET 476 between a first voltage rail 478 and a second voltage rail 480. The first voltage rail 478 receives, from highest voltage selector circuitry (not shown in FIG. 4), a highest voltage Highest_out between the substantially fixed voltage Vfixed and the voltage Vgmax. The second voltage rail 480 receives the voltage VBST.

A gate terminal of the first P-channel MOSFET 474 is coupled to a gate terminal of the first N-channel MOSFET 476. A source terminal of the first P-channel MOSFET 474 is coupled to the first voltage rail 478 and a drain terminal of the first P-channel MOSFET 474 is coupled to a drain terminal of the first N-channel MOSFET 476. The output node 472 of the first control circuitry 470 is coupled to the drain terminals of both the first P-channel MOSFET 474 and the first N-channel MOSFET 476. A source terminal of the first N-channel MOSFET 476 is coupled to the second voltage rail 480.

The first control circuitry 470 is operative to output (at its output node 472) either the highest voltage Highest_out or the voltage VBST, depending on the state of the first P-channel MOSFET 474 and the first N-channel MOSFET 476. When the first P-channel MOSFET 474 is switched on, the first N-channel MOSFET 476 is switched off, such that the first voltage rail 478 is coupled to the output node 472 and the first control circuitry 470 outputs the highest voltage Highest_out. When the first P-channel MOSFET 474 is switched off, the first N-channel MOSFET 476 is switched on, such that the second voltage rail 480 is coupled to the output node 472 and the first control circuitry 470 outputs the voltage VBST.

Similarly, the second control circuitry 490 in this example comprises a second P-channel MOSFET 494 coupled in series with a second N-channel MOSFET 496 between the first voltage rail 478 and the second voltage rail 480.

A gate terminal of the second P-channel MOSFET 494 is coupled to a gate terminal of the second N-channel MOSFET 496. A source terminal of the second P-channel MOSFET 494 is coupled to the first voltage rail 478 and a drain terminal of the second P-channel MOSFET 494 is coupled to a drain terminal of the second N-channel MOSFET 496. The output node 492 of the second control circuitry 490 is coupled to the drain terminals of both the second P-channel MOSFET 494 and the second N-channel MOSFET 496. A source terminal of the second N-channel MOSFET 496 is coupled to the second voltage rail 480.

The second control circuitry 490 is operative to output (at its output node 492) either the highest voltage Highest_out or the voltage VBST, depending on the state of the second P-channel MOSFET 494 and the second N-channel MOSFET 486. When the second P-channel MOSFET 494 is switched on, the second N-channel MOSFET 496 is switched off, such that the first voltage rail 478 is coupled to the output node 492 and the second control circuitry 490 outputs the highest voltage Highest_out. When the second P-channel MOSFET 494 is switched off, the second N-channel MOSFET 496 is switched on, such that the second voltage rail 480 is coupled to the output node 492 and the second control circuitry 490 outputs the voltage VBST.

The first and second control circuitry 470, 490 are configured or controlled (e.g. by multiplexer control circuitry 500) to operate in a complementary anti-phase manner, such that when the output of the first control circuitry 470 is the highest voltage Highest_out, the output of the second control circuitry 490 is the voltage VBST, and when the output of the first control circuitry 470 is the voltage VBST, the output of the second control circuitry 490 is the highest voltage Highest_out.

In one example, the multiplexer control circuitry 500 may comprise non-overlap circuitry (e.g. non-overlapping clock generator circuitry) configured to ensure that an input signal to the second control circuitry 490 remains at the voltage VBST until the output of the first control circuitry 470 (and thus the voltage at the first control node 450 of the first select switch circuitry) has switched to the highest voltage Highest_out, and to ensure that an input signal to the first control circuitry 470 remains at the voltage VBST until the output of the second control circuitry 490 (and thus the voltage at the second control node 460 of the second select switch circuitry) has switched to the highest voltage Highest_out.

To this end, the multiplexer control circuitry 500 may include first multiplexer control logic 510 having a first input 512 coupled to a first feedback path 514 from the output node 492 of the second control circuitry 490 and a second input 516 for receiving a first control signal for causing a change in the output of the first control circuitry 470.

The first multiplexer control logic 510 is configured to output a signal at the voltage VBST to the gate terminals of the first P-channel MOSFET 474 and the first N-channel MOSFET 476 (regardless of any first control signal received at the second input of the first multiplexer control logic 510) until the output of the second control circuitry 490 (and thus the voltage at the second control node 460 of the second select switch circuitry) has switched to the highest voltage Highest_out. Once the output of the second control circuitry 490 (and thus the voltage at the second control node 460 of the second select switch circuitry) has switched to the highest voltage Highest_out, if a first control signal that causes the output of the output of the first control circuitry 470 to transition from Highest_out to VBST is received at its second input 516, the first multiplexer control logic 510 will transmit this first control signal to the gate terminals of the first P-channel and N-channel MOSFETs 474, 476 to cause a change in the output of the first control circuitry 470 from Highest_out to VBST.

The multiplexer control circuitry 500 may further include second multiplexer control logic 520 having a first input 522 coupled to a second feedback path 524 from the output node 472 of the first control circuitry 470 and a second input 526 for receiving a second control signal for causing a change in the output of the second control circuitry 490.

The second multiplexer control logic 520 is configured to output a signal at the voltage VBST to the gate terminals of the second P-channel MOSFET 494 and the second N-channel MOSFET 496 (regardless of any second control signal received at the second input of the second multiplexer control logic 520) until the output of the first control circuitry 470 (and thus the voltage at the first control node 450 of the first select switch circuitry) has switched to the highest voltage Highest_out. Once the output of the first control circuitry 470 (and thus the voltage at the first control node 450 of the first select switch circuitry) has switched to the highest voltage Highest_out, if a second control signal that causes the output of the output of the second control circuitry 490 to transition from Highest_out to VBST is received at its second input 526, the second multiplexer control logic 520 will transmit this second control signal to the gate terminals of the second P-channel and N-channel MOSFETs 494, 496 to cause a change in the output of the second control circuitry 490 from Highest_out to VBST

When the high-side switch 130 of the boost converter circuitry 100 is switched on, Vgmax is equal to VBST+5V (in this example), due to the action of the bootstrap capacitor 140 and the high-side supply generator circuitry 134. Thus, when the high-side switch 130 is switched on, Vgmax is higher than the substantially fixed voltage Vfixed, such that the highest voltage Highest_out is equal to Vgmax.

When the high-side switch 130 of the boost converter circuitry 100 is switched on, the first control circuitry 470 is controlled so as to switch on the first P-channel MOSFET 474 and to switch off the first N-channel MOSFET 476. The voltage at the output node 472 of the first control circuitry 470 is thus equal to Vgmax. The voltage at the output node 492 of the second control circuitry 490 is equal to VBST, due to the complementary operation of the first and second control circuitry 470, 490.

The first control node 450 thus receives a voltage equal to Vgmax, which causes the first and second P-channel MOSFETs 412, 414 to switch off, decoupling the output node 420 from the first input node 410. In this condition, the second diode 418 prevents current flow from the first input node 410 to the output node 420, and the first diode 416 prevents back flow of current from the output node 420 to the first input node 410.

The second control node 460 receives a voltage equal to VBST, which causes the third and fourth P-channel MOSFETs 422, 424 to switch on, thus bypassing the third and fourth diodes 426, 428 and coupling the output node 420 to the second input node 430, such that the output voltage Vg_replica is equal to Vgmax.

When the high-side switch 130 of the boost converter circuitry 100 is switched off, the first control circuitry 470 is controlled so as to switch off the first P-channel MOSFET 474 and to switch on the first N-channel MOSFET 476. The voltage at the output node 472 of the first control circuitry 470 is thus equal to VBST. The voltage at the output node 492 of the second control circuitry 490 is equal to Highest_out, due to the complementary operation of the first and second control circuitry 470, 490.

The first control node 450 thus receives a voltage equal to VBST, which causes the first and second P-channel MOSFETs 412, 414 to switch on, bypassing the first and second diodes 416, 418 and coupling the output node 420 to the first input node 410, such that the output voltage Vg_replica is equal to Vfixed.

The second control node 460 receives a voltage equal to Vgmax, which causes the third and fourth P-channel MOSFETs 422, 424 to switch off, decoupling the output node 420 from the second input node 430. In this condition the third diode 426 prevents current flow from the second input node 430 to the output node 420, and the fourth diode 428 prevents back flow of current from the output node 420 to the second input node 430.

In some examples, the multiplexer circuitry 400 may receive a control signal indicative of the state (switched on or switched off) of the high-side switch 130 of the boost converter circuitry 100 (e.g. from control circuitry of the boost converter circuitry 100) and may control the first and second control circuitry 470, 490 as discussed above in response to this control signal to select between the substantially fixed voltage Vfixed and the voltage Vgmax according to the state (on or off) of the high-side switch 130.

In other examples, the multiplexer circuitry 400 may include detection circuitry (e.g. as part of the multiplexer control circuitry 500) configured to detect the state (switched on or switched off) of the high-side switch 130 of the boost converter circuitry 100 and to output a control signal indicative of the state (on or off) of the high-side switch 130. The multiplexer circuitry 400 may control the first and second control circuitry 470, 490 as discussed above in response to this control signal to select between the substantially fixed voltage Vfixed and the voltage Vgmax according to the state (on or off) of the high-side switch 130. Such detection circuitry may alternatively be provided outside of the multiplexer circuitry 400. Those of ordinary skill in the art will appreciate that such detection circuitry may be implemented in many different ways and will be able to select a suitable implementation.

As discussed above, the first voltage rail 478 receives, from highest voltage selector circuitry, a highest voltage Highest_out between the substantially fixed voltage Vfixed and the voltage Vgmax.

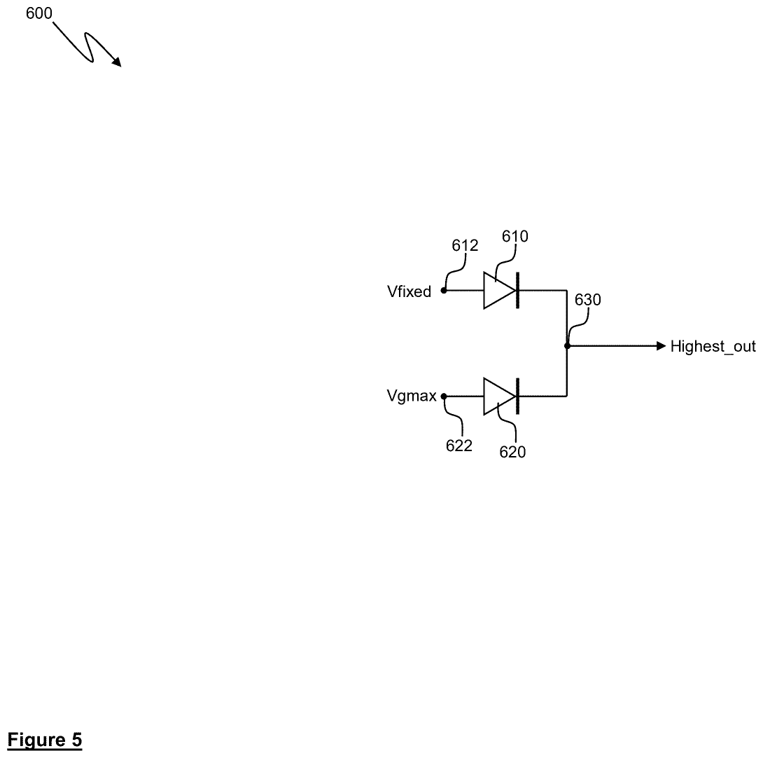

FIG. 5 is a schematic representation of highest voltage selector circuitry suitable for selecting the highest voltage Highest_out between the substantially fixed voltage Vfixed and the voltage Vgmax.

As shown generally at 600 in FIG. 5, the highest voltage selector circuitry comprises a first diode 610 having its anode coupled to a node 612 that receives the substantially fixed voltage Vfixed and its cathode coupled to an output node 630. The highest voltage selector circuitry 600 further comprises a second diode 620 having its anode coupled to a node 622 that is coupled to the floating voltage rail 136 to receive the voltage Vgmax and its cathode coupled to the output node 630.

The highest voltage selector circuitry 600 thus constitutes a diode-OR circuit, where the first and second diodes 610, 620 conduct the substantially fixed voltage Vfixed and the voltage Vgmax, respectively (provided those voltages are positive), to the output node 630, such that and the voltage Highest_out at the output node 630 is the greater of Vfixed and Vgmax (less a diode voltage drop). The first diode 610 prevents reverse current flow from the output node 630 to the node 612 when Vgmax is greater than Vfixed. Similarly, the second diode 620 prevents reverse current flow from the output node 630 to the node 622 when Vfixed is greater than Vgmax.

Those of ordinary skill in the art will readily appreciate that the highest voltage selector circuitry 600 shown schematically in FIG. 5 can be implemented in many different ways, and will be able to select a suitable implementation.

Those of ordinary skill in the art will further appreciate that the highest voltage selector circuitry 600 shown schematically in FIG. 5 could be implemented in such a way as to avoid the voltage drop associated with the diodes 610, 620, e.g. using MOSFETs and current sources, and will be able to select a suitable implementation.

Other circuitry for selecting highest voltage Highest_out between the substantially fixed voltage Vfixed and the voltage Vgmax could be equally employed. Such circuitry could have a microcontroller and associated voltage detection circuitry to detect which of the two voltages is highest and to control the multiplexer circuitry 300 to output the highest voltage Highest_out as the voltage Vg_replica that is supplied to the gates of the replica devices 210, 230.

The foregoing description assumes that the switching circuitry (e.g. the boost converter circuitry) operates in a continuous conduction modes. In switching circuitry (e.g. boost converter circuitry of the kind described above with reference to FIG. 1) that operates in a discontinuous conduction mode, it may be desirable to maintain a level of charge on a bootstrap capacitor (e.g. the bootstrap capacitor 140 of the boost converter circuitry 100 of FIG. 1) in periods in which no current is being conducted by the switching circuitry, e.g. when both the high-side switch 130 and the low-side switch 120 are switched off in the boost converter circuitry 100 of FIG. 1.

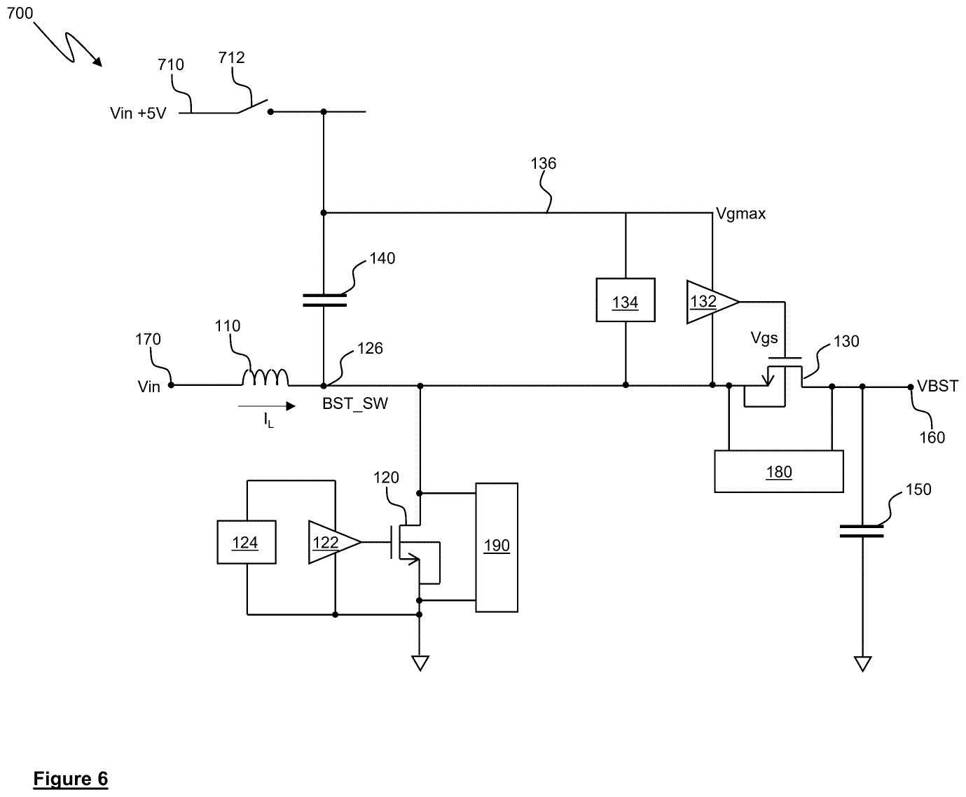

FIG. 6 is a schematic representation of circuitry for maintaining charge on a bootstrap capacitor of switching circuitry when the switching circuitry is operating in a discontinuous conduction mode.

In the circuitry shown generally at 700 in FIG. 6, switching circuitry comprising boost converter circuitry of the kind described above with reference to FIG. 1 is operable in a discontinuous conduction mode, such that in addition to the charging and discharging phases described above, each operational cycle of the boost converter circuitry also includes a non-conduction phase in which both the low-side switch 120 and the high-side switch 130 are switched off. It is desirable to maintain a predefined level of charge on the bootstrap capacitor 140 during the non-conduction phase, to ensure that the high-side switch 130 is able to switch on rapidly once the boost converter circuitry begins a new discharging phase of operation.

To this end, the circuitry 700 includes a power supply rail 710 that receives a constant DC supply voltage, e.g. of a magnitude equal to Vin+5V (i.e. 5 volts greater than the input voltage Vin that is supplied to the boost converter circuitry 100). The power supply rail 710 is coupled to the second terminal of the bootstrap capacitor 140 by a switch 712.

In operation of the circuitry 700, the boost converter circuitry operates in the same way as the circuitry 100 described above with reference to FIG. 1 in a continuous conduction mode. In the continuous conduction mode the switch 712 remains open (i.e. switched off) such that the power supply rail 710 is decoupled from the second terminal of the bootstrap capacitor 140.

In operation of the circuitry 700 in a discontinuous conduction mode, during the non-conduction phase the switch 712 is closed, such that the power supply rail 710 is coupled to the second terminal of the bootstrap capacitor 140. The bootstrap capacitor 140 thus receives charge from the power supply rail 710 in the non-conduction phase, thus maintaining a level of charge on the bootstrap capacitor 140.

In the examples described above with reference, the bootstrap capacitor 140 is associated with the high-side switch 130 of the boost converter circuitry 100. It will be appreciated, however, that the principles outlined herein are equally applicable to a bootstrap capacitor associated with the low-side switch 120 of the boost converter circuitry 100, for example.

Moreover, the principles outlined herein are equally applicable to other types of switching circuitry, including (but not limited to) switching power converter circuitry, switching boost converter circuitry, switching buck converter circuitry, switching buck-boost converter circuitry, switching AC-DC converter circuitry, switching DC-AC converter circuitry, or switching amplifier circuitry (e.g. Class D amplifier circuitry).

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD-or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry for supplying a bias voltage to a replica sense device of current sensing circuitry for a switch of a switching circuit, the circuitry comprising:
multiplexer circuitry configured to receive a first voltage and a second voltage, wherein the first voltage is a floating voltage and the second voltage is a fixed voltage,
wherein the multiplexer circuitry is configured to select and output one of the first voltage and the second voltage, such that the first voltage is output by the multiplexer circuitry when the switch is switched on and the second voltage is output by the multiplexer circuitry when the switch is switched off.

2. The circuitry of claim 1, wherein a magnitude of the second voltage is approximately equal to an expected magnitude of the first voltage when the switch of the switching circuit is switched on.

3. The circuitry of claim 1, wherein the switch comprises a MOSFET (metal oxide semiconductor field effect transistor) and the replica sense device comprises a MOSFET smaller than the MOSFET of the switch.

4. The circuitry of claim 1, wherein the second voltage is of a magnitude sufficient to maintain a common mode voltage for differential amplifier circuitry of the current sensing circuitry.

5. The circuitry of claim 3, wherein the second voltage is of a magnitude sufficient to maintain the replica sense device in a safe operating area thereof.

6. The circuitry of claim 3, wherein the multiplexer is configured to output the selected voltage to a gate of the replica sense device.

7. The circuitry of claim 1, wherein the multiplexer circuitry is configured to select the greater of the first voltage and the second voltage.

8. The circuitry of claim 1, wherein the multiplexer circuitry comprises:
first select switch circuitry configured to be controlled by first control circuitry; and
second select switch circuitry configured to be controlled by second control circuitry.

9. The circuitry of claim 8, wherein:
the first select switch circuitry comprises first and second p-channel MOSFETs coupled in series between a first input node and an output node of the multiplexer circuitry; and
the second select switch circuitry comprises third and fourth p-channel MOSFETs coupled in series between a second input node and the output node of the multiplexer circuitry.

10. The circuitry of claim 9, wherein the first input node receives the second voltage and the second input node receives the first voltage.

11. The circuitry of claim 10, wherein:
the first select switch circuitry is configured to decouple the first input node from the output node of the multiplexer circuitry when the switch is switched on and to couple the first input node to the output node of the multiplexer circuitry when the switch is switched off; and
the second select switch circuitry is configured to couple the second input node to the output node of the multiplexer circuitry when the switch is switched on and to decouple the second input node from the output node of the multiplexer circuitry when the switch is switched off.

12. The circuitry of claim 9, wherein:
the first select switch circuitry comprises a first control node configured to receive an output of the first control circuitry;
the second select switch circuitry comprises a second control node configured to receive an output of the second control circuitry;
the first control circuitry and the second control circuitry are each configured to output the greater of the first voltage and the second voltage.

13. The circuitry of claim 8, wherein the first control circuitry and the second control circuitry each comprise highest voltage selector circuitry configured to output the greater of the first voltage and the second voltage.

14. The circuitry of claim 13, wherein the highest voltage selector circuitry implements an OR circuit.

15. The circuitry of claim 1, wherein the switching circuitry comprises switching power converter circuitry comprising a bootstrap capacitor, the circuitry further comprising a switch configured to selectively couple a power supply rail to the bootstrap capacitor to supply charge to the bootstrap capacitor.

16. The circuitry of claim 15, wherein the circuitry is configured to close the switch to couple the power supply rail to the bootstrap capacitor in a non-conducting phase in operation of the switching power converter circuitry in a discontinuous conduction mode.

17. An integrated circuit comprising the circuitry of claim 1.

18. A host device comprising the circuitry of claim 1, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer.

19. Circuitry for supplying a bias voltage to a replica sense device used in current sensing for a switch of a switching circuit, the circuitry comprising
multiplexer circuitry configured to receive a first voltage and a second voltage, wherein the first voltage is a floating voltage and the second voltage is a fixed voltage,
wherein the multiplexer circuitry is configured to select and output a highest one of the first voltage and the second voltage.

20. Switching power converter circuitry operable in a continuous conduction mode or a discontinuous conduction mode, the switching power converter circuitry comprising:
a bootstrap capacitor for supplying a bootstrap voltage to a power switch of the switching power converter circuitry; and
a power supply rail; and
a switch for selectively coupling the power supply rail to the bootstrap capacitor,
wherein, in operation of the switching power converter circuitry in the discontinuous conduction mode, the switch is closed to couple the power supply rail to the bootstrap capacitor in a non-conducting phase of operation.
